(19) United States
(12) Patent Application Publication
(10) Pub. No.: US 2014/0205865 A1
(43) Pub. Date: Jul. 24, 2014

(54) BATTERY MONITORING SYSTEM, SEMICONDUCTOR DEVICE, BATTERY ASSEMBLY SYSTEM, BATTERY MONITORING IC

(71) Applicant: LAPIS SEMICONDUCTOR CO., LTD., Yokohama-Shi (JP)

(72) Inventor: YOSHIKATSU MATSUO, YOKOHAMA-SHI (JP)

(73) Assignee: LAPIS SEMICONDUCTOR CO., LTD., Yokohama-shi (JP)

(21) Appl. No.: 14/158,906

(22) Filed: Jan. 20, 2014

(30) Foreign Application Priority Data
Jan. 18, 2013 (JP) 2013-007791

(51) Int. Cl. G01R 31/36; H01M 10/48

(52) U.S. Cl. CPC G01R 31/3658; H01M 10/482
USPC 429/7; 324/434

(57) ABSTRACT

Provides a battery monitoring system including a battery cell number setting section that sets each LSI with the respectively individual number of battery cells C to which they are connected. When a command to sequentially measure the battery voltage of the battery cells is input, a cell selection control section compares the setting value with the commanded measurement start battery cell number. When the setting value is equal to or greater, performs measurement in sequence starting from the battery cell corresponding to the measurement start battery cell number. When the setting value is less, measurement is performed in sequence starting from the battery cell corresponding to the setting value. In a boost control section, during when the battery voltages with 3 higher potential battery cells is measured, a power source voltage is boosted by a charge pump and is supplied to first and second buffer amplifier.

### CROSS-REFERENCE TO RELATED APPLICATION

This application claims priority under 35 USC 119 from Japanese Patent Application No. 2013-007791, filed on Jan. 18, 2013, the disclosure of which is incorporated by reference herein.

### BACKGROUND OF THE INVENTION

1. Field of the Invention

The present invention relates to a battery monitoring system, a semiconductor device, a battery assembly system, and a battery monitoring IC.

2. Description of the Related Art

Japanese Patent Application Laid-Open (JP-A) No. 2011-232161 discloses a battery monitoring system configured with ICs provided for measuring the voltage of respective serially connected battery cells. Each of the ICs is provided with terminals for voltage input that match the number of individual battery cells. Further, in JP-A No. 2011-232161, buffer amplifiers provided in each of the ICs are driven by voltages supplied from the battery configured by direct connection of the battery cells.

Further, in JP-A No. 2012-90400, a system equipped with plural battery monitoring ICs, in which the number battery cells to be subjected to measurement differs depending on the IC, is disclosed.

However, when the number of battery cells to be subjected to measurement is different depending on the IC as JP-A No. 2012-90400, sometimes the desired precision is not achieved in the output precision of the buffer amplifier used to measure the battery cell voltage. The output precision of the buffer amplifier affects the measurement precision of voltages of the battery cells.

### SUMMARY OF THE INVENTION

The present invention provides a battery monitoring system, a semiconductor device, a battery assembly system and a battery monitoring IC capable of achieving a desired precision in output precision of a buffer amplifier.

A first aspect of the present invention is a battery monitoring system including: a battery configured with plural battery cells connected together in series; plural semiconductor devices that are connected to a specific number of battery cells of the battery and that are capable of measuring respective voltage values of the specific numbers of battery cells; and a control device capable of instructing the semiconductor devices with the battery cells to be subjected to voltage value measurement, wherein, each of the semiconductor devices includes, a battery cell selection section that selects the battery cells to be subjected to measurement from out of the specific number of the connected battery cells, a first buffer amplifier, to which is input a voltage of one terminal of the battery cell selected by the battery cell selection section, that is capable of outputting a first voltage according to the voltage of the one terminal of the battery cell, and that is driven by a drive voltage supplied from the battery, a second buffer amplifier, to which is input a voltage of the other terminal of the battery cell selected by the battery cell selection section, that is capable of outputting a second voltage according to the voltage of the other terminal of the battery cell, and that is driven by a drive voltage supplied from the battery, a level shifter capable of outputting a difference between the first voltage and the second voltage, a boost section that boosts the drive voltage supplied from the battery to the first buffer amplifier and the second buffer amplifier, a battery cell number setting section that is settable with the specific number, and a control section that is capable of controlling the battery cell selection section and the boost section during performing measurement of voltage values of the battery cells, based on the specific number set in the battery cell number setting section.

A second aspect of the present invention is a semiconductor device that, for a battery configured by connecting plural battery cells together in series, has a specific number of the battery cells out of the plural battery cells connected thereto and is capable of measuring respective voltage values of the connected battery cells, wherein the semiconductor device includes: a battery cell selection section that selects the battery cells to be subjected to measurement from out of the specific number of the connected battery cells; a first buffer amplifier, to which is input a voltage of one terminal of the battery cell selected by the battery cell selection section, that is capable of outputting a first voltage according to the voltage of the one terminal of the battery cell, and that is driven by a drive voltage supplied from the battery; a second buffer amplifier, to which is input a voltage of the other terminal of the battery cell selected by the battery cell selection section, that is capable of outputting a second voltage according to the voltage of the other terminal of the battery cell, and that is driven by a drive voltage supplied from the battery; a level shifter capable of outputting a difference between the first voltage and the second voltage; a boost section that boosts the drive voltage supplied from the battery to the first buffer amplifier and the second buffer amplifier; a battery cell number setting section that is settable with the specific number; and a control section that is capable of controlling the battery cell selection section and the boost section during performing measurement of voltage values of the battery cells, based on the specific number set in the battery cell number setting section.

A third aspect of the present invention is a battery assembly system including: a battery configured with plural battery cells connected together in series; plural battery monitoring ICs that detect respective voltages of the battery cells; and a control IC that is capable of performing instruction to the battery monitoring ICs to detect the respective voltages of each of the battery cells, wherein each of the battery monitoring ICs includes, a first buffer amplifier, to which is input a voltage of one terminal of the battery cell subject to voltage detection, that is capable of outputting a first voltage according to the voltage of the one terminal of the battery cell, and that is driven by a drive voltage supplied from the battery, a second buffer amplifier, to which is input a voltage of the other terminal of the battery cell subject to voltage detection, that is capable of outputting a second voltage according to the voltage of the other terminal of the battery cell, and that is driven by a drive voltage supplied from the battery, a difference output section that outputs a difference between the first voltage and the second voltage, a boost section that is capable of boosting drive voltage supplied from the battery to the first buffer amplifier and the second buffer amplifier, a battery cell number setting section that is settable with a number of the battery cells capable of being detected itself, and a control section that, according to the detection instruction output from the control IC and the number of the battery cells set by the battery cell number setting section, determines the battery cell to be subjected to voltage detection, and determines whether or not to supply a boosted voltage of the battery to the first buffer amplifier and the second buffer amplifier as the drive voltage.

A fourth aspect of the present invention is a battery monitoring IC that, for a battery configured by connecting plural battery cells together in series, detects voltage values of each of the respective battery cells according to an externally input instruction, wherein the battery monitoring IC includes: a first buffer amplifier, to which is input a voltage of one terminal of a battery cell subjected to voltage detection, that is capable of outputting a first voltage according to the voltage of the one terminal of the battery cell, and that is driven by a drive voltage supplied from the battery; a second buffer amplifier, to which is input a voltage of the other terminal of the battery cell subjected to voltage detection, that is capable of outputting a second voltage according to the voltage of the other terminal of the battery cell, and that is driven by a drive voltage supplied from the battery; a difference output section that outputs a difference between the first voltage and the second voltage; a boost section that is capable of boosting drive voltage supplied from the battery to the first buffer amplifier and the second buffer amplifier; a battery cell number setting section that is settable with a number of the battery cells capable of being detected itself; and a control section that, according to the externally input instruction and the number of the battery cells set in the battery cell number setting section, determines the battery cell to be subjected to voltage detection, and determines whether or not to supply a boosted voltage of the battery to the first buffer amplifier and the second buffer amplifier as the drive voltage.

According to the above aspects of the present invention, the present invention may provide a battery monitoring system, a semiconductor device, a battery assembly system and a battery monitoring IC capable of achieving a desired precision in output precision of a buffer amplifier.

### BRIEF DESCRIPTION OF THE DRAWINGS

Exemplary embodiments of the invention will be described in detail with reference to the following figures, wherein:

FIG. 1 is a schematic configuration diagram illustrating an example of a schematic configuration of a battery monitoring system according to a first exemplary embodiment;

FIG. 2 is a schematic configuration diagram illustrating an example of a lowest stage LSI provided to a battery monitoring system of the first exemplary embodiment;

FIG. 3 is a schematic configuration diagram illustrating an example of a highest stage LSI provided to a battery monitoring system of the first exemplary embodiment;

FIG. 4 is configuration diagram illustrating an example of a detailed configuration of a first exemplary embodiment, with a cell selector SW, a first buffer amplifier, a second buffer amplifier and a level shifter;

FIG. 5 is a flow chart illustrating an example of flow of operation in battery voltage measurement of a battery monitoring system of the first exemplary embodiment;

FIG. 6 is a timing chart illustrating an example of a cell selection signal and a boost control signal in each LSI during the operation illustrated in FIG. 5;

FIG. 7 is a circuit diagram illustrating an example of a configuration of a first buffer amplifier and a second buffer amplifier in the first exemplary embodiment;

FIG. 8 is a flow chart illustrating an example of flow of operation in battery voltage measurement of a battery monitoring system of a second exemplary embodiment;

FIG. 9 is a timing chart illustrating an example of a cell selection signal and a boost control signal in each LSI during the operation illustrated in FIG. 8;

FIG. 10 is a timing chart illustrating an example of a cell selection signal and a boost control signal in each LSI of another operation;

FIG. 11 is a flow chart illustrating an example of flow of setting processing when setting the battery cell number setting section by the LSI itself;

FIG. 12 is a timing chart illustrating an example of sequential cell measurement from the lowest potential battery cell;

FIG. 13 is a schematic configuration diagram illustrating an example of an LSI that has a terminal to which a battery cell is not connected on the lower potential side;

FIG. 14 is a flow chart illustrating an example of flow of operation in battery voltage measurement of a battery monitoring system provided with an LSI having a terminal to which a battery cell C is not connected on the lower potential side;

FIG. 15 is a schematic configuration diagram illustrating an example of a lowest stage LSI provided in a conventional battery monitoring system; and

FIG. 16 is a timing chart illustrating an example of a cell selection signal and a boost control signal in each LSI during the operation illustrated in FIG. 15.

### DETAILED DESCRIPTION OF THE INVENTION

Explanation next follows regarding a battery monitoring system according to an exemplary embodiment, with reference to the drawings.

### First Exemplary Embodiment

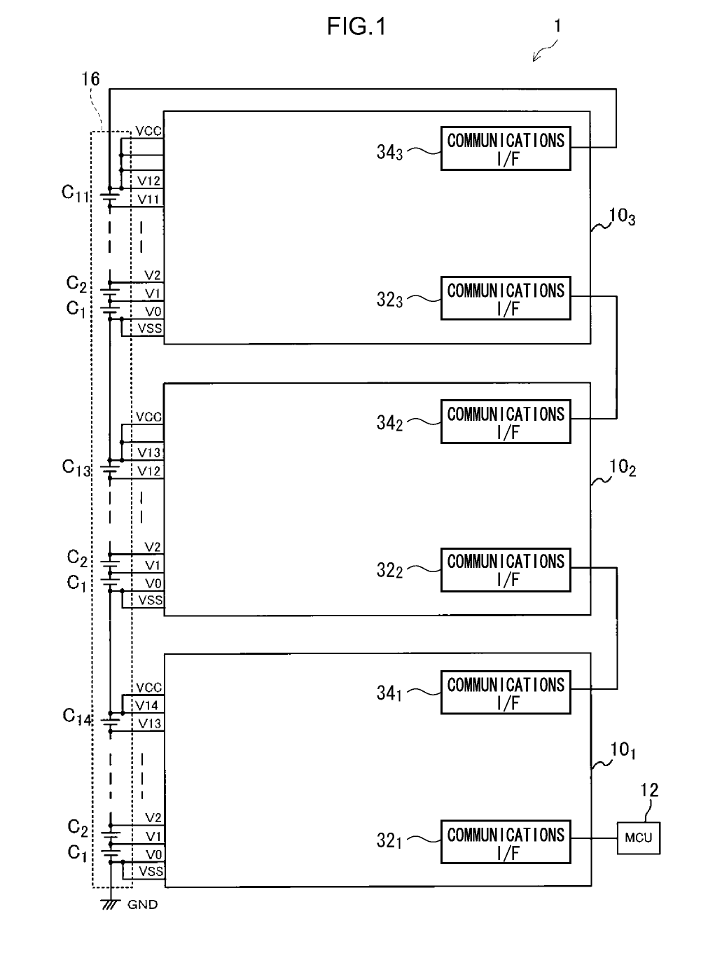

Explanation first follows regarding an overall schematic configuration of a battery monitoring system of the present exemplary embodiment. FIG. 1 illustrates an example of a schematic configuration of a battery assembly system of the present exemplary embodiment.

A battery monitoring system 1 includes Large Scale Integration circuits (LSIs 10 (10₁ to 10₃), a Micro Control Unit (MCU) 12, and a battery 16 configured from a group of battery cells.

The battery 16 is configured from plural battery cells C connected together in series. Lithium ion secondary battery cells is a specific example of the battery cells C, and an example given as the battery voltage is 0.4 to 5.0 V per cell. In the battery 16 of the present exemplary embodiment there are, as a specific example, 39 individual battery cells C connected together in series.

The MCU 12 functions as a control device of the present invention, and the MCU 12 of the present exemplary embodiment has a function to control the battery monitoring system 1 overall, and a function to control operation of each of the LSI 10₁ to LSI 10₃. The MCU 12 is configured by a general purpose microcontroller. The MCU 12 and the lowest stage LSI 10₁ are directly connected together. The MCU 12 and the LSI 10₂ are connected together with the LSI 10₁ therebetween. The MCU 12 and the LSI 10₃ are connected together with the LSI 10₁ and the LSI 10₂ therebetween. In the present exemplary embodiment, during battery voltage measurement of each of the battery cells C, a command for sequential cell measurement (details are given later) is first output from the MCU 12 to the LSI 10₁ as an instruction command to detect the battery voltage of each of the battery cells C. This command is sequentially transmitted to the higher stage LSIs 10 (10₂ and 10₃). Each of the LSIs 10 (10₁ to 10₃) performs measurement of the battery voltage of each of the battery cells C on receipt of the command from the MCU 12.

In the present exemplary embodiment, the MCU 12 is pre-stored with the number of individual connected battery cells C that are connected to each of the LSIs 10 (10₁ to 10₃). The MCU 12 sets this individual connected number in the battery cell number setting sections 40 of each of the LSIs 10 (10₁ to 10₃) (details follow later).

Note that in the present exemplary embodiment, the MCU 12 is employed as a controller, however there is no limitation to the circuit scale of the controller, and a control IC may be employed therefor.

The LSIs 10 (10₁ to 10₃) are each battery monitoring LSIs to monitor (measure) the battery voltages of the battery cells of the connected battery 16. In the present exemplary embodiment, as illustrated in FIG. 1, as a specific example, the LSI 10 has 3 stage serial connections (a daisy chain connection), with the lowest stage referred to as the LSI 10₁, the middle stage referred to as the LSI 10₂, and the highest stage referred to as the LSI 10₃. Note that, when referring to the LSIs collectively this is represented simply by “LSI 10”, with the individual respective suffixes appended when discriminating between the individual LSIs. Moreover, in the present exemplary embodiment, LSIs 10 (battery monitoring LSIs) is employed as a semiconductor device, however there is no limitation to the circuit scale of the semiconductor device, and a battery monitoring integrated circuit (IC) may be employed therefor.

In the battery monitoring system 1 according to the present exemplary embodiment, there are different numbers of individual battery cells C of the battery 16 connected to each of the respective LSIs 10. There are 14 individual battery cells C (C₁ to C₁₄) connected to the LSI 10₁. There are 13 individual battery cells C (C₁ to C₁₃) connected to the LSI 10₂. There are 12 individual battery cells C (C₁ to C₁₂) connected to the LSI 10₃. Note that, when referring to the battery cells C collectively, this is indicated simply by “battery cells C”, with individual respective suffixes appended when discriminating therebetween.

The voltage of the highest stage of each connected battery cell C group (highest electrical potential) is supplied to each of the LSIs 10, as a power source voltage VCC for use as an internal power source. Specifically, a voltage V14 of the high potential side of the battery cell C₁₄ is supplied as the power source voltage VCC to the LSI 10₁. A voltage V13 of the high potential side of the battery cell C₁₃ is supplied as the power source voltage VCC to the LSI 10₂. A voltage V12 of the high potential side of the battery cell C₁₂ is supplied as the power source voltage VCC to the LSI 10₃.

Moreover, the LSIs 10 each include a communication I/F circuit 32 for communicating with the LSIs 10 at lower potentials (on the low voltage side), and with a communication I/F circuit 34 for communicating with the LSIs 10 at higher potentials (on the high voltage side). Note that, when referring collectively to the communication I/F circuits 32 and the communication I/F circuits 34 this is indicated simply by “communication I/F circuits 32” and “communication I/F circuits 342, and individual respective suffixes are appended when discriminating therebetween.

Note that the MCU 12 is connected to the communication I/F circuit 32₁ of the lowest potential LSI 10₁, and various information (signals) related to such topics as battery voltage monitoring of the battery cells C of the battery 16 are transmitted to and from the MCU 12.

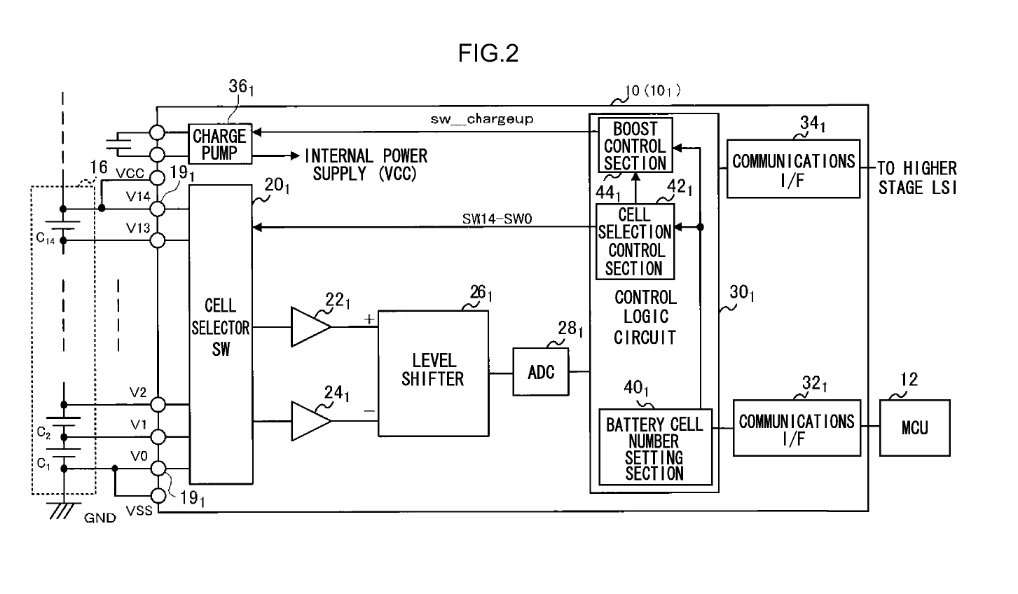

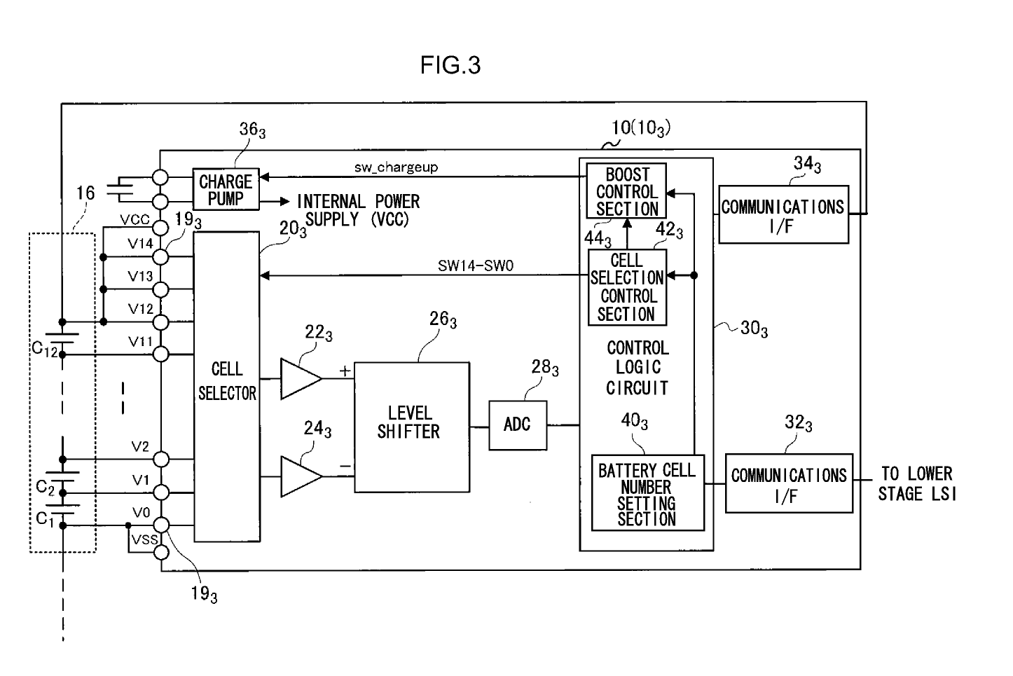

Explanation next follows regarding details of the LSIs 10 according to the present exemplary embodiment. FIG. 2 and FIG. 3 are schematic configuration diagrams illustrating examples of the LSIs 10 according to the present exemplary embodiment. Note that FIG. 2 illustrates the lowest stage LSI 10₁, and FIG. 3 illustrates the highest stage LSI 10₃.

As illustrated in FIG. 2 and FIG. 3, the LSIs 10 of the present exemplary embodiment are each configured including a cell selector SW 20, a first buffer amplifier 22, a second buffer amplifier 24, a level shifter 26, an ADC 28, a control logic circuit 30 serving as a controller of the present invention, the communication I/F circuit 32, the communication I/F circuit 34, and a charge pump 36 serving as a boost section of the present invention. Note that in the following, when referring collectively to the cell selectors SW 20, the first buffer amplifiers 22, the second buffer amplifiers 24, the level shifters 26, the ADCs 28, the control logic circuits 30, the communication I/F circuits 32, the communication I/F circuits 34 and the charge pumps 36 the individual suffixes are omitted, however the individual suffixes are appended when discriminating between which of the LSIs 10 (10₁ to 10₃) they are provided to.

The cell selector SW 20 contains plural switching elements, and selects the battery cell C whose battery voltage is to be measured, based on battery cell selector SW signals (SW0 to SW14) of the control logic circuit 30 (a cell selection controller 42). The highest electrical potential side of the battery cell C selected by the cell selector SW 20 is input to the first buffer amplifier 22. The voltage on the low voltage side of the battery cell C selected by the cell selector SW 20 is input to the second buffer amplifier 24. The level shifter 26 is an analogue level shifter, and the output of the first buffer amplifier 22 is connected to the non-inverting terminal, and the output of the second buffer amplifier 24 is connected to the inverting terminal.

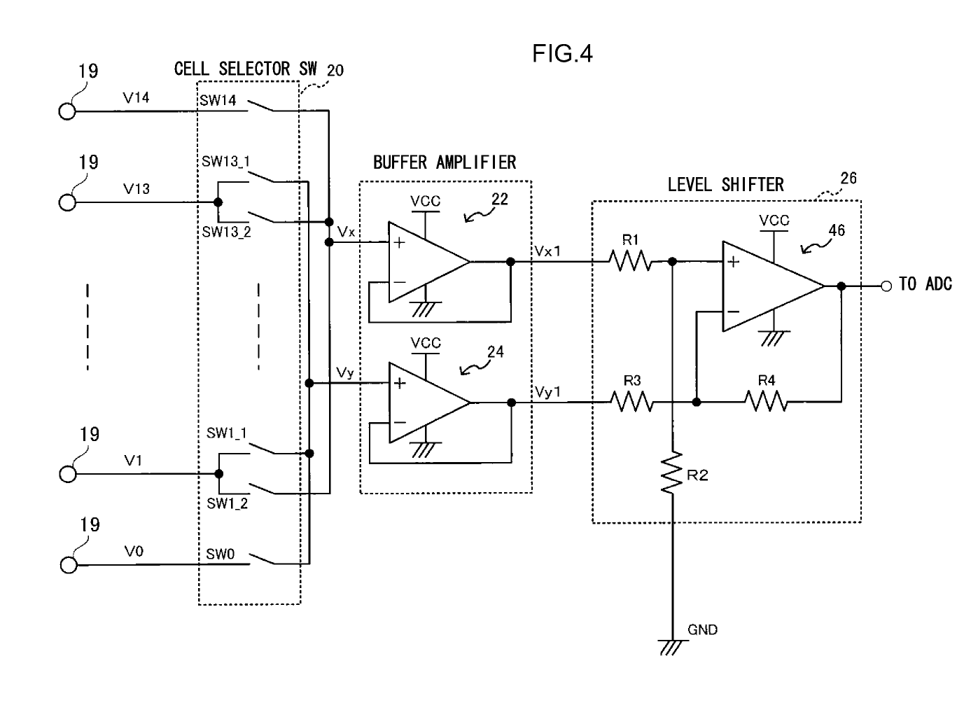

FIG. 4 is a schematic configuration diagram illustrating examples of detailed configurations of the cell selector SW 20, the first buffer amplifier 22, the second buffer amplifier 24 and the level shifter 26 of the present exemplary embodiment.

As illustrated in FIG. 4, the cell selector SW 20 is configured including switching elements SW0 to SW14 for selecting each of the battery cells C₁ to C₁₄. In the present exemplary embodiment, the switching elements SW0 to SW14 all have the same structure.

The outputs of the cell selector SW 20 are connected to the non-inverting terminals of the first buffer amplifier 22 and the second buffer amplifier 24. In the present exemplary embodiment, the switching elements SW1_{—}2, . . . , SW13_{—}2, SW14 of the cell selector SW 20 are connected to the non-inverting terminal of the first buffer amplifier 22. Moreover, the switching elements SW0, SW1_{—}1, . . . , SW13_{—}1 of the cell selector SW 20 are connected to the non-inverting terminal of the second buffer amplifier 24. Note that the inverting terminals of the first buffer amplifier 22 and the second buffer amplifier 24 are connected to their respective outputs (negative feedback).

Note that in the present exemplary embodiment, irrespective of the number of individual battery cells C that are connected to the LSIs 10, the cell selectors SW 20 in all of the LSIs 10 are provided with the same number of switching elements (SW0 to SW14). Moreover, similarly to with the switching elements, all of the LSIs 10 are also provided with the same number of terminals 19 to input with the respective voltages from the battery cells C. Hence, the LSIs 10 with a number of connected battery cells C that is less than the maximum value (14 in the present exemplary embodiment) are, as illustrated in FIG. 3, configured so that the voltage of the high electrical potential side of the highest potential battery cell C is applied to the terminal 19 that does not have a corresponding battery cell C connected thereto (a spare terminal 19). For example, when the battery monitoring system 1 is employed in an environment with a lot of noise, such as installed in a vehicle, sometimes floating noise, such as radiation noise, might flow into the spare terminal 19. In order to prevent this, in the present exemplary embodiment, such spare terminals 19 are not left in this state, but instead a specific voltage is applied thereto.

The first buffer amplifier 22 and the second buffer amplifier 24 are configured with the same structure. Note that in the present exemplary embodiment, voltages Vx1, Vy1 that are the same voltage values as that of the voltages Vx, Vy input from the non-inverting terminals of the first buffer amplifier 22 and the second buffer amplifier 24 are respectively output from their respective output terminals (Vx=Vx1, Vy=Vy1).

In the present exemplary embodiment, the output (Vx1) of the first buffer amplifier 22 is connected to the non-inverting terminal of a buffer amplifier 46 of the level shifter 26 through a detection resistor R1. Moreover, the output (Vy1) of the second buffer amplifier 24 is connected to the inverting terminal of the buffer amplifier 46 of the level shifter 26.

The level shifter 26 functions as a difference output section that outputs a difference between the voltage (Vx1) input from the non-inverting terminal and the voltage (Vy1) input from the inverting terminal, so as to output, to the ADC 28, a difference between the voltage values of both terminal voltages of the battery cell C selected by the cell selector SW 20.

As a specific example of the level shifter 26 of the present exemplary embodiment, as illustrated in FIG. 4, an example is given of a configuration of the first buffer amplifier 22 and the second buffer amplifier 24, with buffer amplifiers 46 of the same structure as each other and with detection resistors R1 to R4 that have the same resistance values as each other

(R1=R2=R3=R4).

Note that in the present exemplary embodiment, as a drive voltage, the first buffer amplifier 22, the second buffer amplifier 24, and the buffer amplifier 46 of the level shifter 26 are driven by the power source voltage VCC supplied from the charge pump 36. Note that in the present exemplary embodiment, a case in which a power source voltage VCC boosted by the charge pump 36 is supplied and a case in which a non-boosted power source voltage VCC is supplied.

The ADC 28 input with the output corresponding to the measurement data of battery voltage output from the level shifter 26 has a function to analogue-to-digital (AD) convert measurement data. The AD converted measurement data is held in a memory or the like, not illustrated in the drawings, within the control logic circuit 30. In the battery monitoring system 1 according to the present exemplary embodiment, the remaining battery capacity of the battery cell C is monitored by the MCU 12 reading the measurement data held in the control logic circuit 30 of each of the LSIs 10.

The control logic circuits 30 have a function of controlling the LSIs 10 overall, based on instructions (control signals and the like) from the MCU 12. The control logic circuits 30 of the present exemplary embodiment are each provided with a battery cell number setting section 40, a cell selection control section 42, and a boost control section 44. The battery cell number setting section 40 serves as a battery cell number setting section of the present invention, and the boost control section 44 and the cell selection control section 42 serve as controllers of the invention.

Each of the battery cell number setting sections 40 has a function to set the number of individual battery cells C connected to its own LSI 10, and is, for example, configured by a register or a memory. The present exemplary embodiment is configured to enable writing from the MCU 12 to the battery cell number setting section 40. The cell selection control section 42 serves as the battery cell selection section according to the present invention and outputs battery cell selection SW signals (SW0 to SW14) to the cell selector SW 20 instructing battery cell C measurement.

The boost control section 44 outputs to the charge pump 36 a boost control signal sw_chargeup indicating an instruction to boost the power source voltage VCC input from the battery 16. The battery cell voltage measurement precision required in the LSIs 10 generally needs to be within a tolerance range of a few mV to about few tens of mV, and extremely high precision is not required. The power source voltage VCC supplied as the internal power supply voltage to the first buffer amplifier 22, the second buffer amplifier 24 and the level shifter 26 accordingly needs to be set higher than the measurement input voltage selected by the cell selector SW 20. In the first buffer amplifier 22 and the second buffer amplifier 24, the actual drive voltage of each of the buffer amplifiers becomes a lower value than the power source voltage VCC supplied from the battery 16 according to the threshold value of MOS transistors configuring the first buffer amplifier 22 and the second buffer amplifier 24. For example, in the first buffer amplifier 22, sometimes the supplied power source voltage VCC and the voltage value input from the battery cell C oppose each other due to input of the voltage of the high electrical potential side of the battery cell C. Namely, in the first buffer amplifier 22, sometimes the voltage Vx input to the non-inverting terminal and the drive voltage VCC are values close to each other. Therefore in the present exemplary embodiment, when the battery voltage of the higher potential battery cell C is measured, for a specific number of battery cells C, or over a specific duration for measuring the specific number of the battery cells C, control is performed such that instruction is given by the boost control signal sw_chargeup to the charge pump 36 to control so as to boost the input power source voltage VCC from the battery 16.

In the present exemplary embodiment, the battery cell number setting section 40 is connected to the cell selection control section 42 and the boost control section 44, and selection of the cell selector SW 20, and whether or not the first buffer amplifier 22 and the second buffer amplifier 24 are boosted by the charge pump 36, is determined according to the setting values of the battery cell number setting section 40.

The communication I/F circuit 32 has a function to perform transmission and reception of various signals to and from the LSI 10 at a lower stage. Note that in the lowest stage LSI 10₁, the communication I/F circuit 32 is connected to the MCU 12 (see FIG. 2).

The communication I/F circuit 34 has a function to perform transmission and reception of various signals to and from the LSI 10 at a higher stage. Note that, in the highest stage LSI 10₃, the communication I/F circuit 34₃ is connected to the high electrical potential side (power source voltage VCC) of the battery 16 (battery cell C) (see FIG. 3). Due to connecting in this manner, the electrical potential of the input terminal of the communication I/F circuit 34₃ may be fixed, thereby enabling it to be suppressed from becoming a floating node. Note that, in such cases, the GND (VSS) level of the LSI 10 that is at the higher stage to the LSI 10₃ (a hypothetically provided LSI 10 since one is not actually provided) and the power source voltage VCC of the LSI 10₃ become the same electrical potential. The signal electrical potential of the input terminal of the communication I/F circuit 34₃ accordingly becomes 0V (no electrical potential difference).

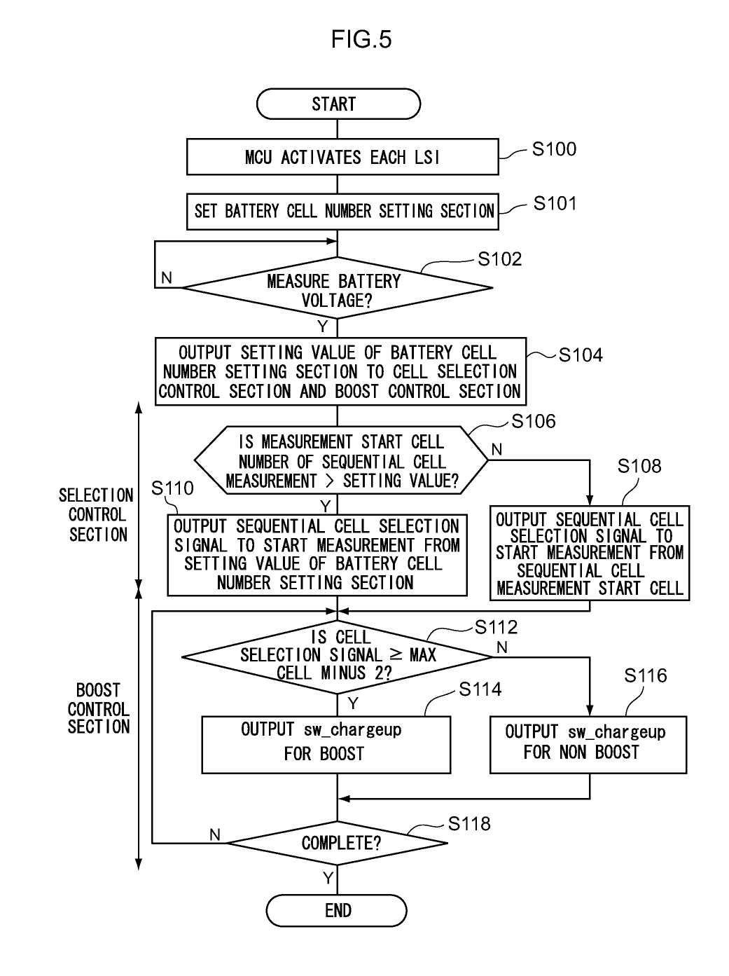

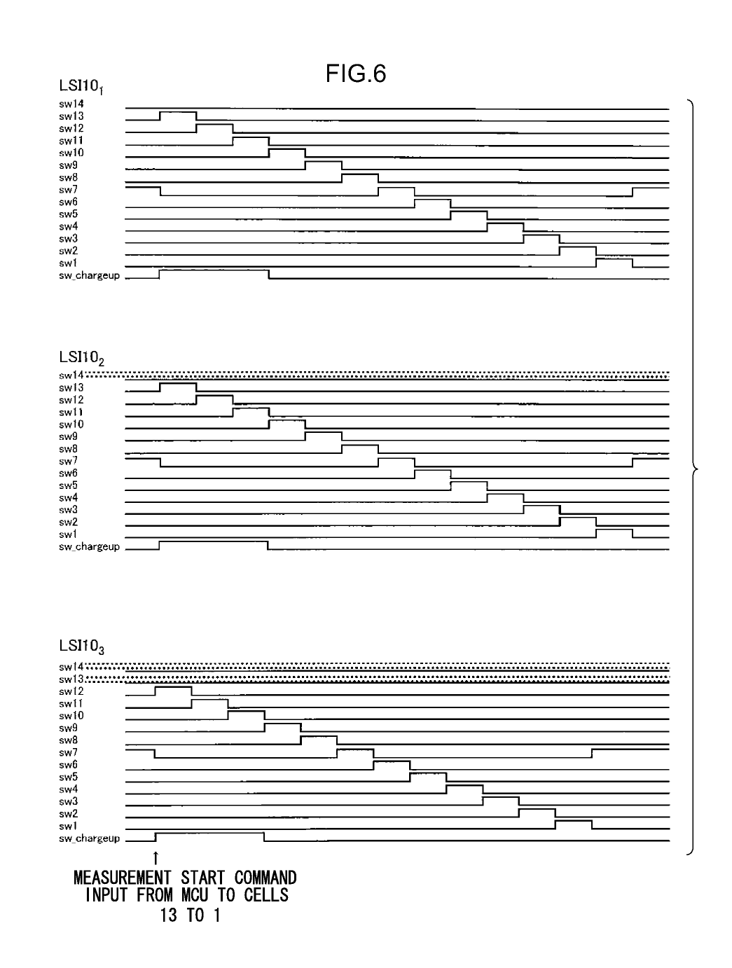

Explanation next follows regarding operation in each of the LSIs 10 in the battery monitoring system 1 of the present exemplary embodiment during measurement of the battery voltage of the battery cells C, sequentially from the high potential (the high electrical potential side). FIG. 5 is a flow chart illustrating an example of flow of operation in battery voltage measurement. Moreover, FIG. 6 is an example of timing charts of cell selection signals and boost control signals in each of the LSIs 10 during the present operation.

The operation illustrated in FIG. 5 is, for example, executed when power is switched on to the battery monitoring system 1 and the LSIs 10, and in cases such as when it is detected that the battery 16 has been connected to the LSIs 10. Note that execution of the present operation is not limited to such cases.

First, at step S100, the MCU 12 actuates each of the LSIs 10, for example when power is switched on to the battery monitoring system 1 and the LSIs 10, or in cases such as when it is detected that the battery 16 has been connected to the LSIs 10. In response thereto, each of the LSIs 10 performs specific processing to discern which stage they are positioned at.

At the next step S101, the respective number of individual connected battery cells C is set in each of the battery cell number setting sections 40 themselves. In the present exemplary embodiment, the MCU 12 is capable of discerning the number of individual battery cells C connected to each of the LSIs 10 by, for example, reading out from a pre-stored memory or the like. The MCU 12 writes the number of individual connected battery cells C to the battery cell number setting section 40 of the control logic circuit 30 of each of the LSIs 10. In the present exemplary embodiment, as a specific example, “14” is written to the battery cell number setting section 40₁ of the LSI 10₁, “13” is written to the battery cell number setting section 40₂ of the LSI 10₂, and “12” is written to the battery cell number setting section 40₃ of the LSI 10₃.

At the next step S102, determination is made as to whether or not to start measuring the battery voltage of the battery cells C. In the present exemplary embodiment, each of the LSIs 10 adopts a standby state until a measurement start instruction is input from the MCU 12 through the communication I/F circuit 32 and the communication I/F circuit 34. When, however, a measurement start instruction has been input from the MCU 12, processing proceeds to step S104 to start measuring the battery voltage. Note that, in the present exemplary embodiment, when an instruction to measure battery voltage is issued, the MCU 12 commands all the LSIs 10 with the battery cell C number to be measured in sequence. The battery cell C number to be measured in sequence is common to all of the LSIs 10, irrespective of the number individual battery cells C actually connected. Explanation next follows, as a specific example, of a case in which the MCU 12 has commanded each of the LSIs 10 with a measurement start battery cell number “13”.

At step S104 the setting value of the battery cell number setting section 40 is input to the cell selection control section 42 and the boost control section 44.

At the next step S106, the cell selection control section 42 that has been input with the setting value compares the measurement start battery cell number for performing sequential cell measurement with the setting value of the battery cell number setting section 40, and processing proceeds to step S108 when the measurement start battery cell number is smaller than the setting value, or processing proceeds to step S110 when the measurement start battery cell number is greater than the setting value. Note that when the measurement start battery cell number and the setting value of the battery cell number setting section 40 are the same as each other in comparison of the measurement start battery cell number and the setting value of the battery cell number setting section 40, processing may proceed to step S108 or processing may proceed to step S110, however in the present exemplary embodiment processing proceeds for example to step S108.

In the LSI 10₁, the measurement start battery cell number is “13”, and the setting value of the battery cell number setting section 40 is “14”, and so since the measurement start battery cell number is smaller than the setting value processing proceeds to step S108. In a similar manner, in the LSI 10₂ the measurement start battery cell number is “13” and the setting value of the battery cell number setting section 40 is “13”, and so since the measurement start battery cell number is the same as the setting value processing proceeds to step S108. At step S108, the cell selection control section 42 outputs to the cell selector SW 20 the cell selection signal (SW0 to SW13) to start measurement, in sequence from the battery cell C (C₁₃) of the measurement start battery cell number, and then processing proceeds to step S112. By so doing, as illustrated in the timing charts of FIG. 6, lower potential battery cells C are selected by the cell selector SW 20 in sequence from the battery cell C₁₃ to the battery cell C₁, and measurement data is held in the control logic circuit 30.

However, in the LSI 10₃, the measurement start battery cell number is “13” and the setting value of the battery cell number setting section 40 is “12”, and so since the measurement start battery cell number is larger than the setting value processing proceeds to step S110. In step S110, the cell selection control section 42 outputs in sequence to the cell selector SW 20 the cell selection signal (SW0 to SW14) for starting measurement from the battery cell C corresponding to the setting value of the battery cell number setting section 40, and then processing proceeds to step S112. Thereby, as illustrated in the timing chart of FIG. 6, in the LSI 10₃ the battery cells C are selected by the cell selector SW 20 in from the battery cell C₁₂ to the battery cell C₁ in sequence towards the lower potential, and the measurement data is held in the control logic circuit 30.

As illustrated in the timing chart of FIG. 5, in the battery monitoring system 1 of the present exemplary embodiment, the battery cells C that are being measured at the same timing (those whose switching element of the cell selector SW 20 are in the ON state) are not the same across all of the LSIs 10.

At the next step S112, in the boost control section 44, determination is made as to whether or not the cell selection signal (the number of the battery cell C or the switching element indicated by the selection signal) is a specific value or higher. In the present exemplary embodiment, the specific value is the setting value of the battery cell number setting section 40 minus 2.

In the present exemplary embodiment, the power source voltage VCC supplied from the battery 16 is boosted by the charge pump 36 during performing measurement of the battery voltage for the 3 higher potential cells out of the connected battery cells C. This is therefore the reason the determination of the present step is performed in the present exemplary embodiment.

Processing proceeds to step S114 when the cell selection signal at step S112 is the setting value minus 2 or greater, and a boost control signal sw_chargeup to perform boost is output to the charge pump 36. The boosted power source voltage VCC is thereby supplied to the first buffer amplifier 22 and the second buffer amplifier 24. However, processing proceeds to step S116 when the cell selection signal is less than the setting value minus 2, and a boost control signal sw_chargeup that indicates not to perform boost is output to the charge pump 36. The power source voltage VCC is accordingly supplied unaltered from the battery 16 to the first buffer amplifier 22 and the second buffer amplifier 24. Moreover, at the next step S118 after step S114 and step S116, determination is made as to whether or not the battery voltage has been measured for all of the battery cells C, and processing returns to step S112 when measurement is not yet complete, the present processing by the boost control section 44 is repeated, and then the present processing is ended when measurement has been completed.

More specifically, as illustrated in the timing chart of FIG. 6, in the LSI 10₁ and LSI 10₂, during measurement of the battery cell C₁₃, the battery cell C₁₂, and the battery cell C₁₁, an H level boost control signal sw_chargeup is output from the boost control section 44 to the charge pump 36. In response thereto, the boosted power source voltage VCC is supplied from the charge pump 36 to the first buffer amplifier 22 and the second buffer amplifier 24. Moreover, during measurement of the battery cell C₁₀ to the battery cell C₁, an L level boost control signal sw_chargeup is output from the boost control section 44 to the charge pump 36. In response thereto, the non-boosted power source voltage VCC is supplied from the charge pump 36 to the first buffer amplifier 22 and the second buffer amplifier 24. Note that in the present exemplary embodiment, the charge pump 36 boosts the power source voltage VCC when input with the H level boost control signal sw_chargeup, and the charge pump 36 does not boost the power source voltage VCC when input with the L level boost control signal sw_chargeup.

Similarly, in the LSI 10₃, during measurement of the battery cell C₁₂, the battery cell C₁₁, and the battery cell C₁₀, the H level boost control signal sw_chargeup is output from the boost control section 44 to the charge pump 36, and boost is performed. Moreover, during measurement of the battery cell C₉ to the battery cell C₁, the L level boost control signal sw_chargeup is output from the boost control section 44 to the charge pump 36, and boost is not performed.

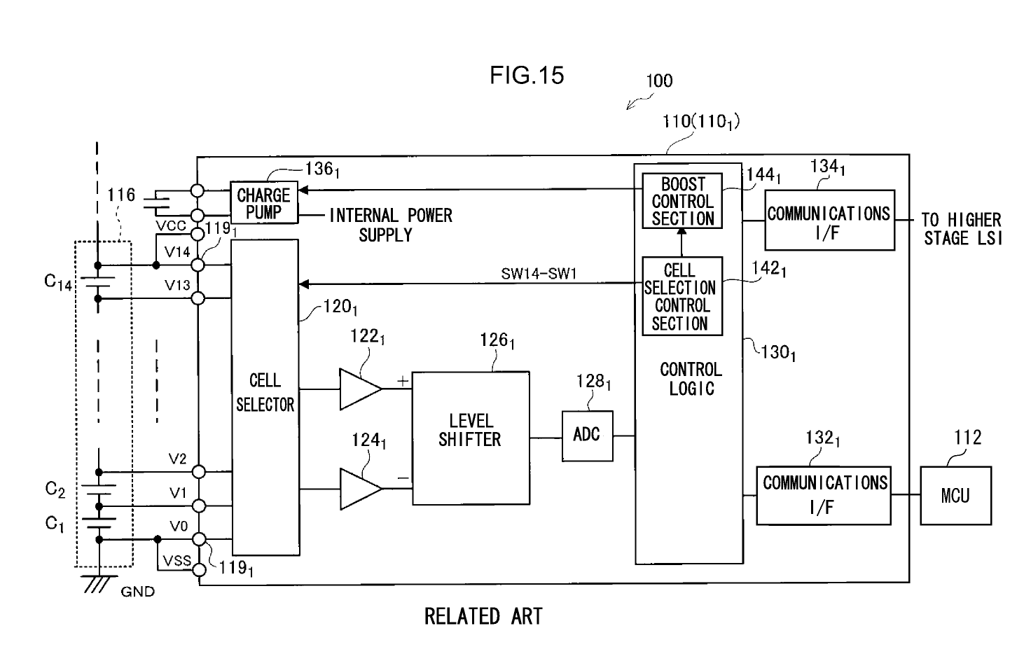

Explanation next follows regarding operation in a battery monitoring system configured by conventional LSIs, to give a comparison to the battery monitoring system 1 (LSIs 10) of the present exemplary embodiment. FIG. 15 is a schematic configuration diagram illustrating a schematic configuration of an example of a conventional LSI 110. Note that the conventional LSI 110 illustrated in FIG. 15 corresponds to the lowest stage LSI 10₁ of the present exemplary embodiment. Moreover, although not illustrated in the drawings, a conventional battery monitoring system 100, similarly to the battery monitoring system 1 of the present exemplary embodiment, also has 3 LSIs 110 connected together in a daisy chain. The conventional LSIs 110 lack the battery cell number setting sections 40 provided to each of the LSIs 10 of the present exemplary embodiment. Thus in the LSIs 110, each of the LSIs 110 is not capable of discerning the number of battery cells C that it is actually itself connected to. Note that, although detailed explanation is omitted regarding other configuration of the LSIs 110 in a conventional battery monitoring system 100, configuration is substantially similar to that of the LSIs 10 of the present exemplary embodiment, other than in that there is no respective battery cell number setting section 40 provided therein.

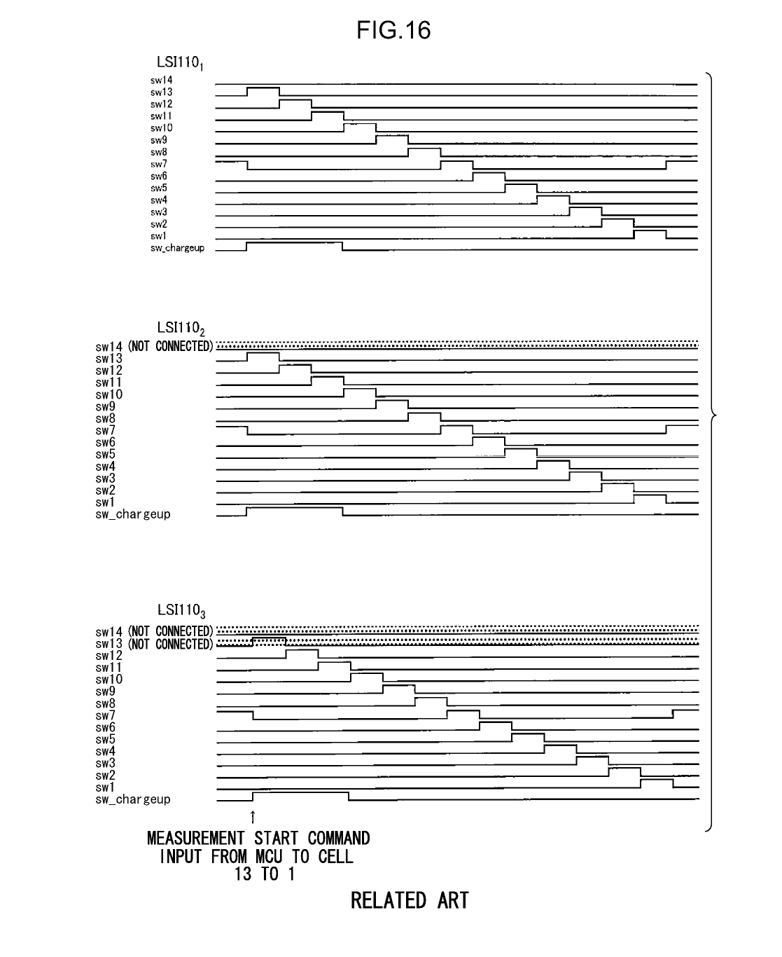

FIG. 16 is a timing chart of an example of operation of a conventional battery monitoring system (LSIs 110). FIG. 16 corresponds to the timing chart illustrated in FIG. 6 of the battery monitoring system 1 (LSIs 10) of the present exemplary embodiment. In a conventional battery monitoring system 100, similarly to in the present exemplary embodiment as explained above, sequential measurement commands indicating the same measurement start battery cell number are output from a MCU 112 at the same time to all of the LSIs 110. In the timing chart illustrated in FIG. 16, similarly to in the present exemplary embodiment as explained above, the measurement start battery cell number is “13”, the number of battery cells C connected to the LSI 110₁ is “14”, the number of battery cells C connected to the LSI 110₂ is “13”, and the number of battery cells C connected to the LSI 110₃ is “12”. A boost control section 144 drives a charge pump 136 during the measurement time of 3 cells worth of the battery cells C from the measurement start battery cell number, and a power source voltage VCC supplied from a battery 116 is boosted.

Consequently, as illustrated in FIG. 16, in all of the LSIs 110, the cell selection signal is output from a cell selection control section 142 to a cell selector SW 120 so as to measure the battery cell C₁₃, the battery cell C₁₂ and the battery cell C₁₁. Moreover, during the period of time corresponding thereto, a H level boost control signal sw_chargeup is output from the boost control section 144 to the charge pump 136, and the power source voltage VCC is boosted. However, in the highest stage LSI 110₃, there are actually only 12 battery cells C connected, and there is no battery cell C₁₃ connected. In the highest stage LSI 110₃, the power source voltage VCC is not actually boosted by the charge pump 36 over the period in which the battery cell C₁₂, the battery cell C₁₁, and the battery cell C₁₀ are being measured. Thus relatedly, during measurement of the battery cell C₁₀, when a boosted power source voltage VCC should be being supplied to the buffer amplifiers, a non-boosted power source voltage VCC is actually supplied to the first buffer amplifier 122 and the second buffer amplifier 124. Accordingly, deterioration in the measurement precision of the first buffer amplifier 122 and the second buffer amplifier 124 may occur.

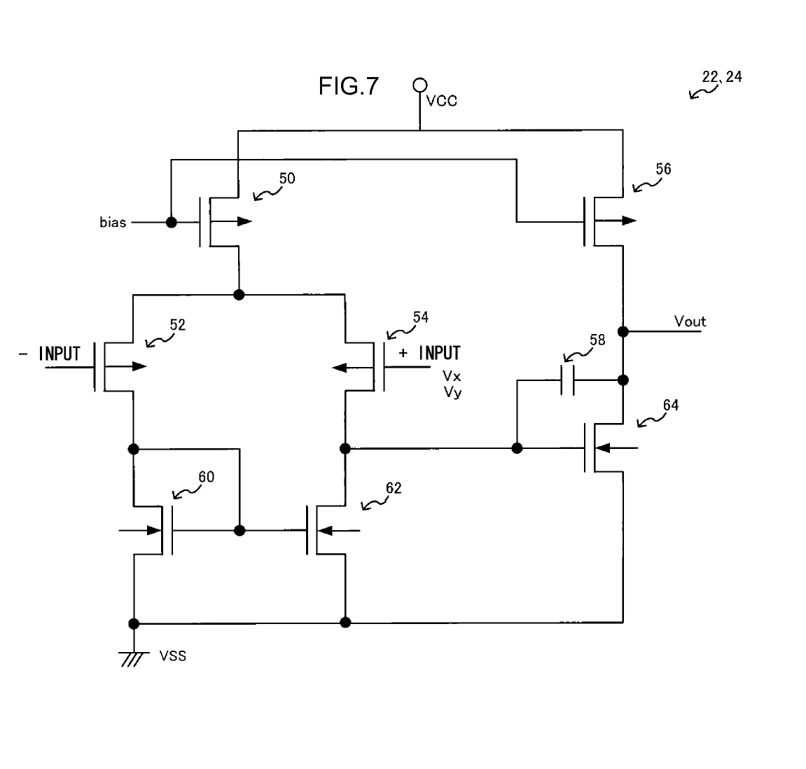

Explanation next follows regarding a specific example of such measurement precision deterioration. FIG. 7 is a circuit diagram of an example of a configuration of a first buffer amplifier 22 and the second buffer amplifier 24. Note that the related first buffer amplifier 122 and second buffer amplifier 124 are also configured similarly to FIG. 7. The first buffer amplifier 22 and the second buffer amplifier 24 include PMOS transistors 50, 52, 54, 56, a condenser 58, and NMOS transistors 60, 62, 64. The power source voltage VCC is supplied to the source terminals of the PMOS transistors 50, 56. In the PMOS transistors 50, 56, due to the influence of the threshold value voltage, the voltage on the drain terminal side becomes power source voltage VCC minus the threshold value voltage. However, the voltages Vx, Vy are input from the battery cell C to the gate terminal of the PMOS transistor 54. There are therefore sometimes occasions when the power source voltage VCC minus the threshold value voltage opposes the voltages Vx, Vy, and in such situations issues of deterioration in measurement precision arise. For example, in such cases, since each of the above MOS transistors in the first buffer amplifier 22 and the second buffer amplifier 24 are operating in the saturated region, there is a large output offset voltage, and the measurement precision deteriorates due to the influence of the output offset voltage.

However, in the battery monitoring system 1 of the present exemplary embodiment, the battery cell number setting section 40 is provided in the control logic circuit 30, and number of the battery cells C actually connected to each of the LSIs 10 is set in the battery cell number setting section 40. The battery cell number setting section 40 is connected to the cell selection control section 42 and the boost control section 44 to input the setting value thereto. When the battery cell C battery voltage sequential measurement commands are input from the MCU 12 to the LSIs 10, the cell selection control section 42 compares the setting value to the measurement start battery cell number commanded from the MCU 12, and when the setting value is the measurement start battery cell number or greater, measurement of battery voltage is performed by sequential selection with the cell selector SW 20 from the battery cell C corresponding to the measurement start battery cell number. However, when the setting value is less than the measurement start battery cell number, measurement of battery voltage is performed by sequential selection with the cell selector SW 20 from the battery cell C corresponding to the setting value. In the boost control section 44, the power source voltage VCC input from the battery 16 is boosted by the charge pump 36 over the period of measuring the battery voltage of the battery cells C corresponding to the higher potential 3 cells out of the connected battery cells C, and the boosted power source voltage VCC is supplied to the first buffer amplifier 22 and the second buffer amplifier 24. Specifically, in the LSI 10₁, during the period in which the battery voltage of the battery cells C₁₃, C₁₂, C₁₁ is being measured, the boosted power source voltage VCC is supplied to the first buffer amplifier 22 and the second buffer amplifier 24. Moreover, in the LSI 10₂, during the period in which the battery voltage of the battery cells C₁₃, C₁₂, C₁₁ is being measured, the boosted power source voltage VCC is supplied to the first buffer amplifier 22 and the second buffer amplifier 24. Moreover, in the LSI 10₃, during the period in which the battery voltage of the battery cells C₁₂, C₁₁, C₁₀ is being measured, the boosted power source voltage VCC is supplied to the first buffer amplifier 22 and the second buffer amplifier 24.

In the thus configured battery monitoring system 1 of the present exemplary embodiment with each of the LSIs 10 connected together in a daisy chain, when there are LSIs 10 contained with different numbers of connected battery cells C, even though commands to start sequential measurement of battery cell voltage are transmitted at the same time from the MCU 12 to all of the LSIs 10, the output precision of the first buffer amplifier 22 and the second buffer amplifier 24 may achieve the desired precision. Consequently, the battery monitoring system 1 of the present exemplary embodiment may measure all of the battery cells C without deterioration of the measurement precision.

In particular, for LSIs 10 for which mass production is required, situations in which the desired voltage of the battery 16 (the total number of battery cells C) is different for each customer, and it is not always the case that there is a battery cell C connected to each of all of the terminals 19 of the respective LSIs 10. However, even in such situations, in the battery monitoring system 1 (the LSIs 10) of the present exemplary embodiment the desired precision may still be achieved in the output precision of the first buffer amplifier 22 and the second buffer amplifier 24.

### Second Exemplary Embodiment

In the first exemplary embodiment above, the cell selection control section 42 controls the switching elements of the cell selector SW 20 for selection according to the setting value of the battery cell number setting section 40. Explanation next follows regarding the present exemplary embodiment in which the boost control section 44 controls boost of the charge pump 36 according to the setting value of the battery cell number setting section 40.

Note that where configuration and operation is similar to that of the first exemplary embodiment this will be stated, and detailed explanation thereof omitted.

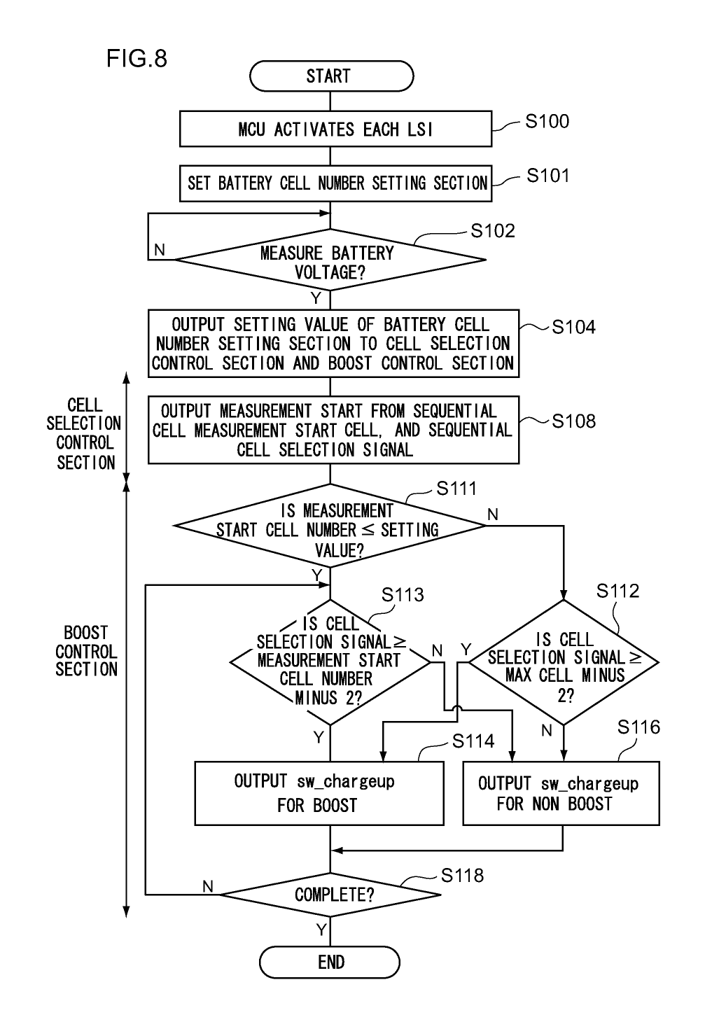

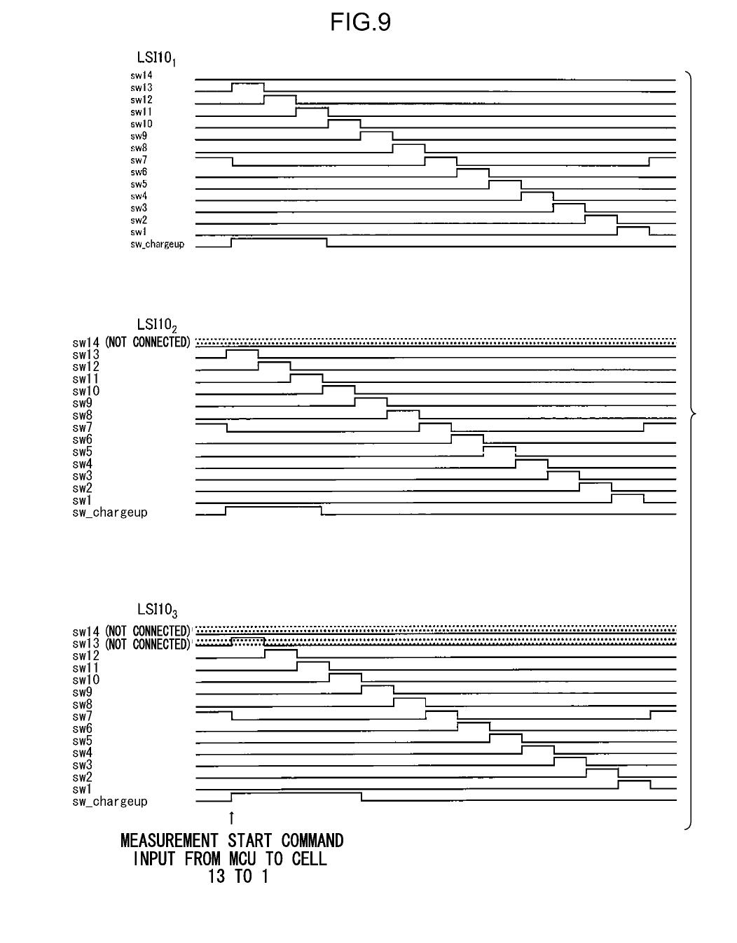

The configurations of the battery monitoring system 1 and the LSIs 10 of the present exemplary embodiment are similar to those of the first exemplary embodiment, and so detailed explanation thereof is omitted. In the present exemplary embodiment, however, the operation when sequentially measuring the battery voltages of the battery cells C in each of the LSIs 10 from the higher potential (high electrical potential side) differs from that of the first exemplary embodiment, and so explanation follows regarding such operation. FIG. 8 is a flow chart illustrating an example of flow of operation of battery voltage measurement in the present exemplary embodiment. FIG. 9 is an example of a timing chart of cell selection signals and boost control signals in each of the LSIs 10 during the present operation.

The operation illustrated in FIG. 8 corresponds to the operation of the first exemplary embodiment (see FIG. 5). In the present exemplary embodiment, similarly to in the first exemplary embodiment, for example, the present operation is executed such as when power is switched on to the battery monitoring system 1 and the LSIs 10, or when it is detected that a battery 16 has been connected to the LSIs 10.

Step S100 to step S104 respectively correspond to step S100 to step S104 of the first exemplary embodiment (see FIG. 5).

At step S100, the MCU 12 actuates each of the LSIs 10. At the next step S101, the MCU 12 sets the respective number of individual connected battery cells C in each of the battery cell number setting sections 40 of each of the LSIs 10. In the present exemplary embodiment, as a specific example, “14” is written to the battery cell number setting section 40₁ of the LSI 10₁, “13” is written to the battery cell number setting section 40₂ of the LSI 10₂, and “12” is written to the battery cell number setting section 40₃ of the LSI 10₃

At the next step S102, determination is made in each of the LSIs 10 as to whether or not to start measuring the battery voltage of the battery cells C, and battery voltage measurement is started when a measurement start instruction has been input from the MCU 12. Note that in the present exemplary embodiment, the MCU 12 commands the LSIs 10 uniformly with the number of the battery cell C to be measured in sequence. Explanation next follows, as a specific example, a case in which the MCU 12 has commanded each of the LSIs 10 with a measurement start battery cell number “13”. Next at step S104 the setting value of the battery cell number setting section 40 is input to the cell selection control section 42 and the boost control section 44.

In the present exemplary embodiment, processing proceeds to step S108 (corresponding to step S108 of the first exemplary embodiment) after step S104. At step S108, the cell selection control section 42 outputs to the cell selector SW 20 the cell selection signal (SW0 to SW13) to start measurement, in sequence from the battery cell C (C₁₃) of the measurement start battery cell number, and then processing proceeds to step S111. By so doing, as illustrated in the timing charts of FIG. 9, lower potential battery cells C are selected by the cell selector SW 20 in sequence from the battery cell C₁₃ to the battery cell C₁, and measurement data is held in the control logic circuit 30.

Thus in the present exemplary embodiment, the cell selection control section 42 starts measurement in sequence from the measurement start battery cell number battery cell C, irrespective of the setting value of the battery cell number setting section 40. As illustrated in the timing chart of FIG. 9, in the battery monitoring system 1 of the present exemplary embodiment, battery cells C measured at the same timing (those whose switching element of the cell selector SW 20 are in the ON state) are the same across all of the LSIs 10.

In the following processing, step S112, and step S114 to step S118 correspond to step S112, and step S114 to step S118 of the first exemplary embodiment (FIG. 5). Note that in the present exemplary embodiment, the period of power source voltage VCC boost by the charge pump 36 differs from that of the first exemplary embodiment, and processing (steps) that differ from those of the first exemplary embodiment is explained in detail.

At the next step S111, the measurement start battery cell number commanded from the MCU 12 is compared against the setting value of the battery cell number setting section 40. Processing proceeds to step S112 when the measurement start battery cell number is smaller than the setting value, and processing proceeds to step S113 when the measurement start battery cell number is larger than the setting value. Note that processing may proceed to step S112 or may proceed to step S113 when the measurement start battery cell number and the setting value are found to be equal in the comparison of the measurement start battery cell number and the setting value of the battery cell number setting section 40, however in the present exemplary embodiment processing proceeds, for example, to step S112.

In the present exemplary embodiment, processing proceeds to step S112 since in the LSI 10₃ the measurement start battery cell number exceeds the setting value.

At step S112, in the boost control section 44, determination is made as to whether or not the cell selection signal (the number of the battery cell C or the switching element indicated by the selection signal) is the setting value of the battery cell number setting section 40 minus 2. This determination is performed in order to measure the battery voltage of the 3 higher potential cells out of the actually connected battery cells C. In the LSI 10₃ during measurement of 4 cells, battery cells C₁₃ to battery cell C₁₀, processing proceeds to step S114. At step S114, as illustrated in FIG. 9, the H level boost control signal sw_chargeup is output from the boost control section 44 to the charge pump 36 to perform boost. However, during measurement of the battery cell C₉ to battery cell C₁, processing proceeds to step S116. At step S116, as illustrated in FIG. 9, the L level boost control signal sw_chargeup is output from the boost control section 44 to the charge pump 36. In the present exemplary embodiment, the charge pump 36 does not perform voltage boost in response to this signal. A non-boosted power source voltage VCC is accordingly supplied from the charge pump 36 to the first buffer amplifier 22 and the second buffer amplifier 24.

On the other hand, in the LSI 10₁ and LSI 10₂, processing proceeds to step S113 since the measurement start battery cell number is the setting value or lower at step S111. At step S113, determination is made as to whether or not the cell selection signal is the measurement start battery cell number minus 2 or greater in the boost control section 44. This determination is performed in order to measure the battery voltage of the 3 higher potential cells from the battery cell C corresponding to the measurement start battery cell number. In the LSI 10₁ and the LSI 10₂, processing proceeds to step S114 during measurement of 3 cells, battery cells C₁₃ to battery cell C₁₁. At step S114, as illustrated in FIG. 9, the H level boost control signal sw_chargeup is output from the boost control section 44 to the charge pump 36. In the present exemplary embodiment, the charge pump 36 performs boost in response to this signal. A boosted power source voltage VCC is accordingly supplied from the charge pump 36 to the first buffer amplifier 22 and the second buffer amplifier 24.

On the other hand, during measurement of the battery cell C₁₀ to battery cell C₁, processing proceeds to step S116. At step S116, as illustrated in FIG. 9, the L level boost control signal sw_chargeup is output from the boost control section 44 to the charge pump 36. In the present exemplary embodiment, the charge pump 36 does not perform voltage boost in response to this signal. A non-boosted power source voltage VCC is accordingly supplied from the charge pump 36 to the first buffer amplifier 22 and the second buffer amplifier 24.

Moreover, at step S118 that follows on from step S114 and step S116, determination is made as to whether or not measurement of the battery voltages has been completed for all of the battery cells C, and the present processing is repeated when measurement is not yet complete, and the present processing is ended when measurement is complete.

Thus in the present exemplary embodiment, as illustrated in the timing chart of FIG. 9, the period over which the power source voltage VCC is boosted by the charge pump 36 (the period the boost control section 44 outputs the H level boost control signal sw_chargeup) is different in the LSI 10₁ and LSI 10₂ to that of the LSI 10₃. Thus in the present exemplary embodiment, when battery voltage measurement has been instructed based on the measurement start battery cell number, based on the setting value of the battery cell number setting section 40 and the measurement start battery cell number, the boost control section 44 controls to supply the power source voltage VCC boosted by the charge pump 36 to the first buffer amplifier 22 and the second buffer amplifier 24 until measurement of the battery cells C instructed for measurement (selected by the cell selector SW 20), starting from the instructed battery cell C with the measurement start battery cell number, has been completed for the 3 higher potential cells of the battery cells C that are actually connected.

Thus in the battery monitoring system 1 of the present exemplary embodiment, each of the LSIs 10 are connected together in a daisy chain, and when there are LSIs 10 that are connected to different numbers of individual battery cells C present, although commands to start sequential measurement of battery cell voltage are transmitted at the same time from the MCU 12 to all of the LSIs 10, the desired output precision of the first buffer amplifier 22 and the second buffer amplifier 24 may be achieved, similarly to in the first exemplary embodiment. Consequently, the present exemplary embodiment may enable measurement of all of the battery cells C without deterioration in measurement precision.

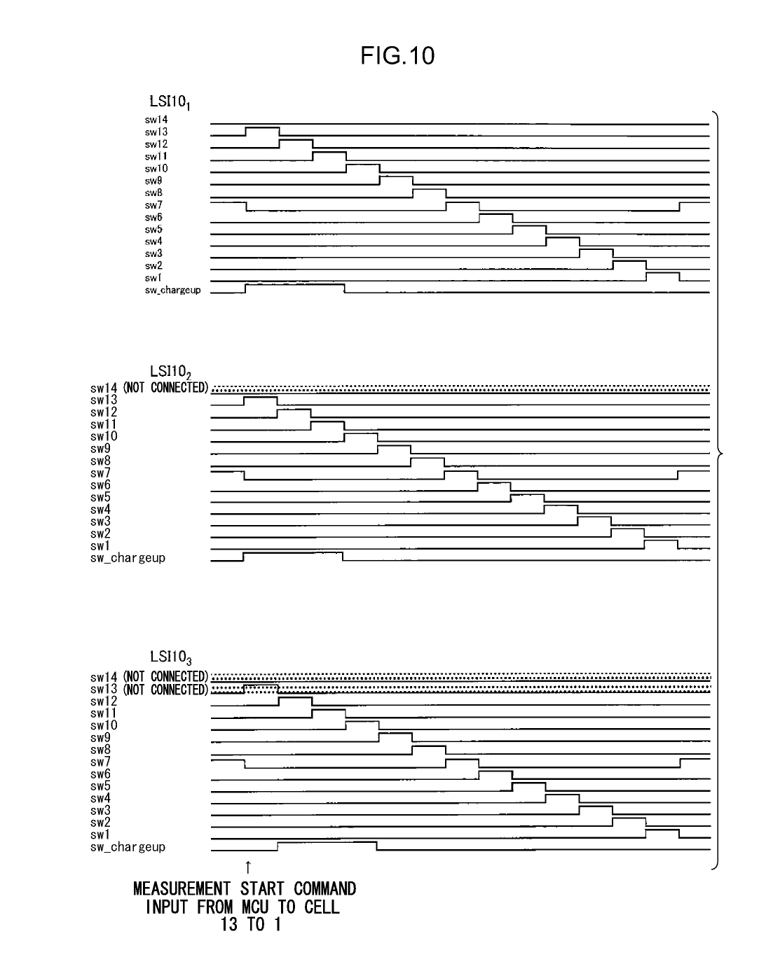

Note that in the present exemplary embodiment, an example is given of controlling the length of the boost period as control by the boost control section 44 of the boost of the charge pump 36 according to the setting value of the battery cell number setting section 40. However, the present invention is not limited thereto. For example, boost timing may be controlled. An example of a timing chart in such a case of boost timing control is illustrated in FIG. 10. As illustrated in FIG. 10, similar operation to that described above (see FIG. 9) is performed in the LSI 10₁ and LSI 10₂. However, in the LSI 10₃, the power source voltage VCC is not boosted by the charge pump 36 during the period for driving the cell selector SW 20 (SW 14) to measure a battery cell C₁₃ that is not actually connected. The non-boosted power source voltage VCC is accordingly supplied to the first buffer amplifier 22 and the second buffer amplifier 24. Then, during measurement of the battery cell C₁₂ to the battery cell C₁₀, the H level boost control signal sw_chargeup is output from the boost control section 44. Boost of the power source voltage VCC is performed by the charge pump 36 in response to this signal, and the boosted power source voltage VCC is supplied to the first buffer amplifier 22 and the second buffer amplifier 24.

Note that in the present exemplary embodiment, although cases in which the boost control section 44 performs control of boost of the charge pump 36 according to the setting value of the battery cell number setting section 40 are different to that in the first exemplary embodiment, there is no measurement actually performed. However, output of the H level cell selection signal from the cell selection control section 42 is performed irrespective of whether or not measurement is performed, resulting in the switching elements of the cell selector SW 20 being driven. Thus from the perspective of suppressing unnecessary driving, control of the cell selector SW 20 by the cell selection control section 42 is preferably performed similarly to that in the first exemplary embodiment.

Moreover, in each of the above exemplary embodiments, as illustrated in the timing charts (FIG. 6, 8, 9), over the duration when the battery voltage of the battery cells C is not being measured, a state is adopted in which the cell selection signal SW7 at H level is output from the cell selection control section 42 to the cell selector SW 20, and L level is output for the cell selection signals SW1 to SW6 and SW8 to SW14, with the battery cell C7 in a selected state. Adopting this approach applies a stable electrical potential, and also enables rapid transition to the high electrical potential side or the low voltage side when measurement is performed.

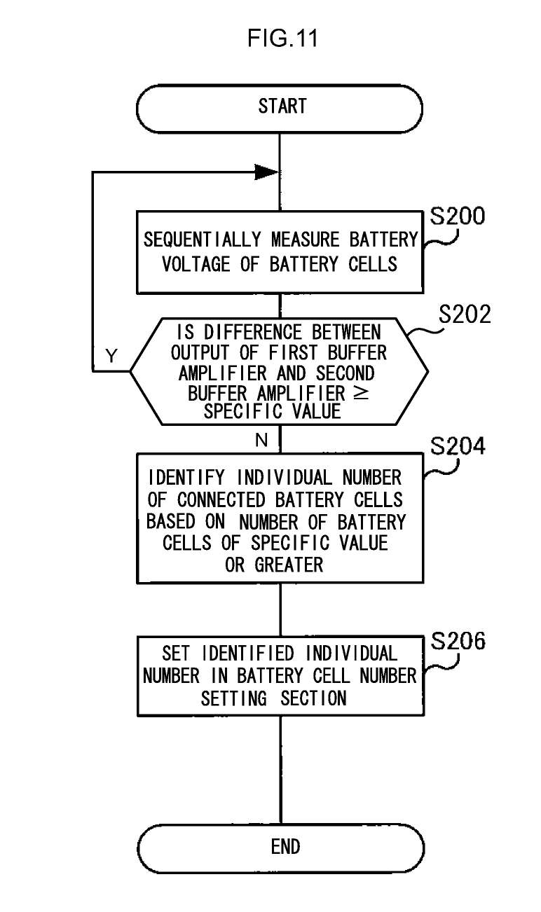

Note that in each of the above exemplary embodiments, the individual numbers of battery cells C connected to the battery cell number setting section 40 of each of the LSIs 10 is set by the MCU 12. However, the present invention is not limitation thereto. For example, each of the LSIs 10 themselves may identify (detect) the number of connected battery cells C, and set this in the battery cell number setting sections 40. Explanation follows regarding a specific example of such a case. FIG. 11 is a flow chart illustrating an example of flow of setting processing when the LSIs 10 themselves set the battery cell number setting sections 40. Note that the present processing may, for example, be performed in place of the processing of step S101 of the operation of the battery monitoring system 1 as explained in each of the above exemplary embodiments. The present processing is, for example, executed by the control logic circuit 30.

At step S200, cell selection signals are output in sequence by the cell selection control section 42 to the cell selector SW 20, and battery voltage of battery cells C is measured. Note that in such cases measurement may be performed starting from the battery cell C at the side of the lowest electrical potential.

At the next step S202, determination is made as to whether or not there is a difference between output of the first buffer amplifier 22 and output of the second buffer amplifier 24, namely whether or not the output of the level shifter 26 is a specific value or greater. When there is no battery cell C connected, the difference between the first buffer amplifier 22 and the second buffer amplifier 24 (the output of the level shifter 26) is less than the specific value. Hence when the output of the level shifter 26 is the specific value or greater this may be interpreted as there being a battery cell C connected thereto. Note that as specific value or greater here, a value may be employed in consideration of the specification of the level shifter 26, or a value determined in consideration of a permissible range such as by testing in advance.

Accordingly, when the difference is the specific value or greater, processing returns to step S200 since there is actually a connected battery cell C, and the present processing is repeated. However, when the difference is less than the specific value, processing proceeds to step S204 since there is no connected battery cell C. Note that processing is performed in this manner in the present exemplary embodiment since sequential measurement is performed from the low voltage side battery cell C. However, the processing of step S200 to S202 may be performed for all of the battery cells C, and the number of battery cells C of the specific value or above (or the number of battery cells C less than the specific value) counted.

At step S204, the number of individual connected battery cells C is identified based on the number of the battery cells C of the specific value or greater, and then at the next step S206 the current processing is ended after setting the identified individual number in the battery cell number setting section 40.

According to such processing, the LSIs 10 are themselves able to set the individual number of connected battery cells C irrespective of whether there is setting from the MCU 12 or not.

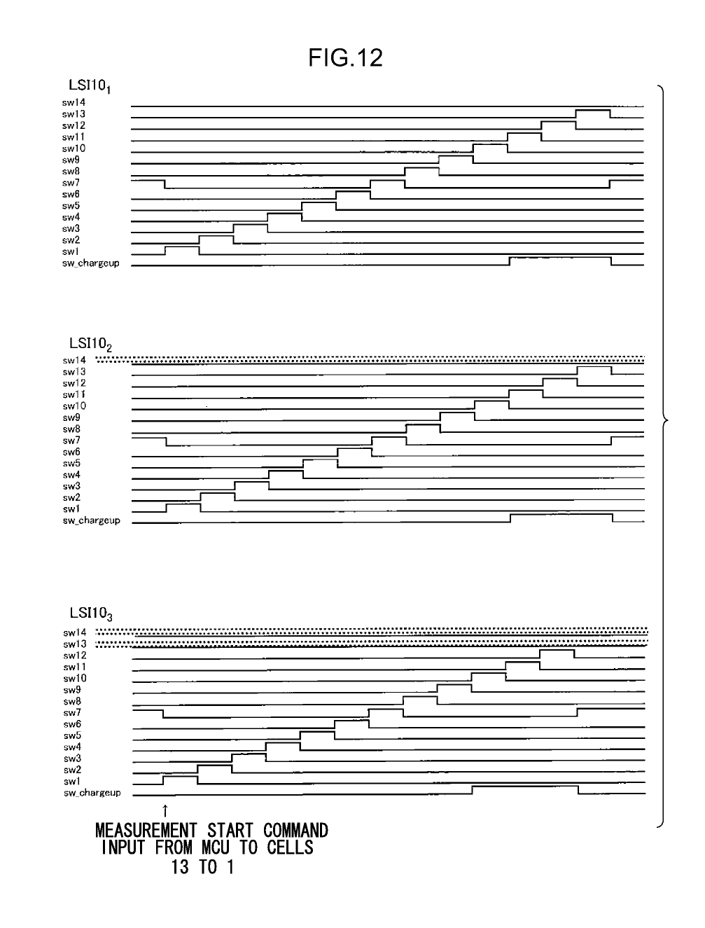

Moreover, in each of the above exemplary embodiments, measurement of the battery voltage of each of the battery cells C (sequential cell measurement) is performed from the highest potential battery cell C. However the present invention is not limited thereto. For example sequential cell measurement may be performed from the lowest potential battery cell C. FIG. 12 is a timing chart illustrating a case in which sequential cell measurement is performed from the lowest potential battery cell C.

Moreover, each of the above exemplary embodiments is configured such that the MCU 12 is connected to the lowest stage LSI 10 (10₁). However the present invention is not limited thereto. For example, the MCU 12 and the respective communication I/F circuits 32 of each of the LSIs 10 may be connected in a configuration such that each type of signal (command) is input from the MCU 12 to all of the LSIs 10 at the same time.

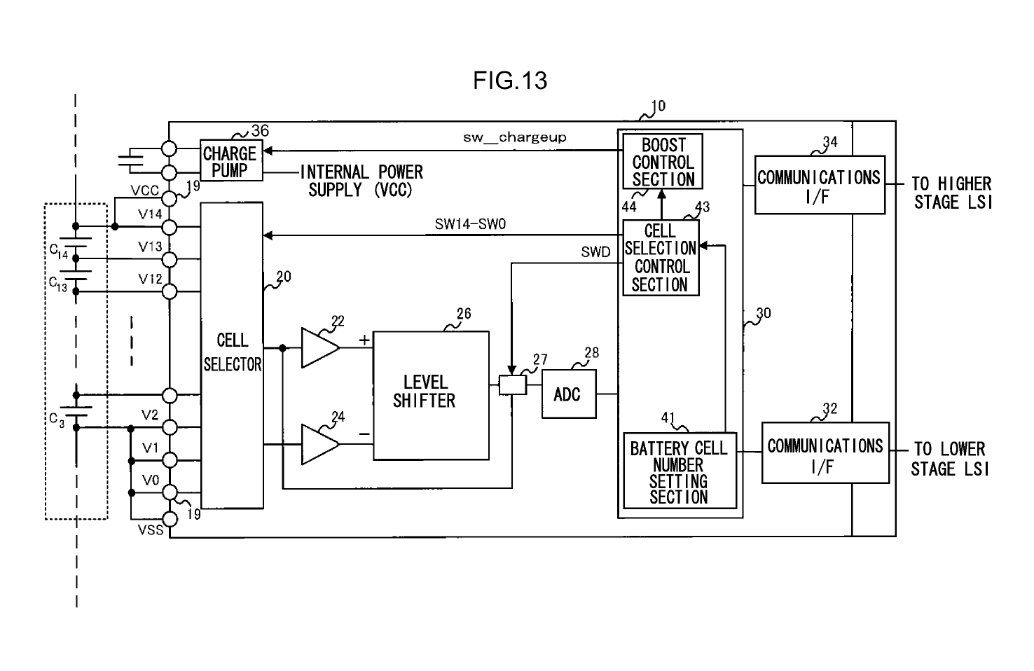

Moreover, explanation has been given in each of the exemplary embodiments described above of cases in which the individual number of connected battery cells C is different, with a LSI 10 that has a terminal 19 not connected to a battery cell C on the higher potential side. In contrast thereto, there are situations in which there is a LSI 10 with a terminal 19 not connected to a battery cell C on the lower potential side. FIG. 13 illustrates an example of a schematic configuration of a LSI 10 with a terminal 19 not connected to a battery cell C on the lower potential side. In such cases, since the voltage (VSS) uses by the second buffer amplifier 24 as the reference on the lower potential side differs depending on the LSI 10, there would sometimes be cases in which the output precision would not achieve the desired value. When measurement is performed of the lowest potential battery cell C, a voltage VSS (GND) is input to the non-inverting terminal of the second buffer amplifier 24. The GND of the second buffer amplifier 24 is at an equivalent electrical potential to the voltage VSS, and since this results in each of the MOS transistors in the second buffer amplifier 24 (see FIG. 7) operating in unsaturated regions, there is a larger output offset voltage. This sometimes results in deterioration in measurement precision due to the influence of the output offset.

In such cases, a battery cell number setting section 41 similar to the battery cell number setting section 40 of the present invention may be provided to set the number of the battery cell C with the lowest potential from out of the connected battery cells C, and then specific processing performed so as to output based on the setting value. As specific processing, for example, processing to operate each of the MOS transistors of the second buffer amplifier 24 in the saturated region may be performed. Moreover, for example, processing may be performed therefor to change the voltage input to the ADC 28 to an appropriate voltage when each of the MOS transistors of the second buffer amplifier 24 operate in the non-saturated region. FIG. 13 illustrates an example of an LSI 10 in which processing is performed to change the voltage input to the ADC 28 to an appropriate voltage. The LSI 10 illustrated in FIG. 13 is equipped with a switching element 27. The switching element 27 switches the voltage input to an ADC 28 between either the output of a level shifter 26 or the non-inverting terminal of the first buffer amplifier 22, according to a control signal SWD input from a cell selection control section 43.

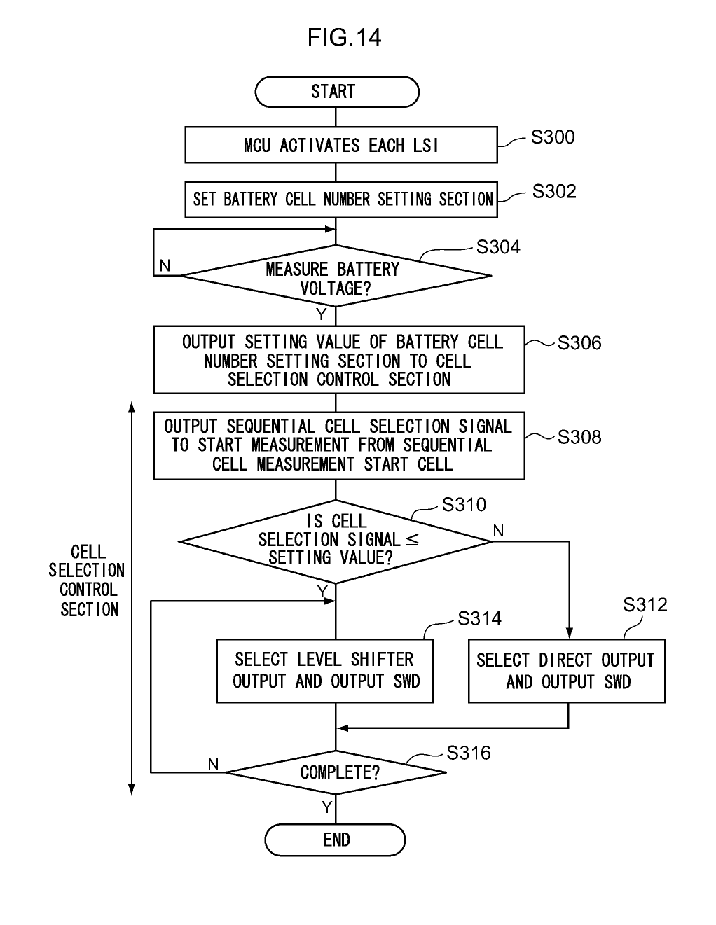

FIG. 14 is a flow chart illustrating an example of operation flow for battery voltage measurement in a battery monitoring system equipped with the LSI 10 illustrated in FIG. 13. Note that this operation contains some operation that is substantially the same as that of each of the above exemplary embodiments (see FIGS. 5 and 8), and so detailed explanation will be omitted for operation that is substantially the same. Similarly to in each of the above exemplary embodiments, after starting the present operation, the MCU 12 actuates each of the LSIs 10 at step S300, corresponding to step S100 of each of the above exemplary embodiments. The next step S302 corresponds to step S101 in each of the above exemplary embodiments, and at step S302 the number of the lowest potential connected battery cell C is set in the battery cell number setting section 41. At the next step S304, corresponding to step S102 of each of the above exemplary embodiments, a battery voltage measurement command is input, and processing proceeds to step S306. At step S306, corresponding to step S104 of each of the above exemplary embodiments, the setting value of the battery cell number setting section is output to the cell selection control section 43. At next step S308, corresponding to step S108 of each of the above exemplary embodiments, sequential cell measurement is started in sequence from the measurement start battery cell number instructed from the MCU 12, and cell selection signals sequentially output to the cell selector SW 20.

At the next step S310, determination is made as to whether or not a cell selection signal is a setting value or lower. Processing proceeds to step S312 when the cell selection signal is greater than the setting value. In such cases, output of the level shifter 26 is selected in order to perform setting of the battery cell C at a higher potential (higher electrical potential) than the lowest potential, and the control signal SWD that inputs this output to the ADC 28 is output from the cell selection control section 43 to the switching element 27. However, when the cell selection signal is equivalent to the setting value, in order to perform setting of the lowest potential battery cell C, the input of the non-inverting terminal of the first buffer amplifier 22 (namely, the voltage directly output from the cell selector SW 20 to the first buffer amplifier 22) is selected, and the control signal SWD to input this voltage to the ADC 28 is output from the cell selection control section 43 to the switching element 27. The voltage of the high potential side of the lowest potential battery cell C is input to the non-inverting terminal of the first buffer amplifier 22. In the lowest potential battery cell C, since the voltage on the high potential side=the measurement voltage, deterioration in measurement precision may be suppressed by outputting this input to the ADC 28.

The final step S316 corresponds to step S118 of each of the above exemplary embodiments, and the present processing is repeated until measurement of all of the battery cells C is completed, and when measurement is complete the present processing is ended.

Note that in the above step S310, processing proceeds to step S314 even though the cell selection signal is less than the setting value. When the cell selection signal is less than the setting value, sometimes instruction is made to measure a non-connected battery cell C, and the cell selector SW 20 selects a terminal 19 without a connected battery cell C. In such cases, the voltage of the high potential side of the lowest potential battery cell C is input to the non-inverting terminal of the first buffer amplifier 22 and the non-inverting terminal of the second buffer amplifier 24. Thus, in the present exemplary embodiment, the input of the non-inverting terminal of the first buffer amplifier 22 (namely, the voltage directly output from the cell selector SW 20 to the first buffer amplifier 22) is selected, and the control signal SWD that inputs this voltage to the ADC 28 is output from the cell selection control section 43 to the switching element 27. This thereby enables deterioration of measurement to be suppressed, as mentioned above. Note that operation when the cell selection signal is less than the setting value is not limited thereto. For example, measurement operation of the battery cell C may not be performed when the cell selection signal is less than the setting value, namely configuration such that the terminal 19 is not selected by the cell selector SW 20.

Moreover, explanation has been given in each of the above exemplary embodiments of cases in which there are a pair of the first buffer amplifier 22 and the second buffer amplifier 24 provided (cases in which one of each are provided). However, the present invention is not limited thereto. For example, configuration may be made with the first buffer amplifier 22 and the second buffer amplifier 24 provided for each of the connected battery cells C. Note that, when the numbers of the first buffer amplifiers 22 and the second buffer amplifiers 24 are less than the number of the battery cells C, the surface area of the LSIs 10 may be made smaller.

Moreover, in each of the above exemplary embodiments, the individual number of the battery cells C provided in the battery 16, and the individual number of the connected battery cells C to each of the LSIs 10, and the individual numbers of LSIs 10 are merely examples, and there is no limitation thereto. For example, the individual numbers of connected battery cells C connected to each of the LSIs 10 may be different for all of the LSIs 10, or there may be LSIs 10 with the same number of connected battery cells C as each other within the plural LSIs 10.

Moreover, although explanation has been given in each of the above exemplary embodiments of the invention applied to solve the issues noticed that arise in the battery monitoring system 1 having plural LSIs 10 connected together in a daisy chain, the system the invention is applied to is not limited thereto. Even in cases in which there is only a single LSI 10, similar issues arise when a terminal 19 without a connected battery cell C is present, and so the present invention may be applied to such a battery monitoring system 1 equipped with only a single LSI 10.

Moreover, the configuration including the battery monitoring system 1, the LSIs 10, the MCU 12 and the control logic circuit 30 and the like, and each of the operations explained in each of the above exemplary embodiments are merely examples thereof, and obvious various modifications are possible according to the circumstances within a range not departing from the main intention of the present invention. Moreover, obviously combinations may be made of configuration elements from each of the above exemplary embodiments.

What is claimed is:

1. A battery monitoring system comprising:
a battery configured with a plurality of battery cells connected together in series;
a plurality of semiconductor devices that are connected to a specific number of battery cells of the battery and that are capable of measuring respective voltage values of the specific numbers of battery cells; and
a control device capable of instructing the semiconductor devices with the battery cells to be subjected to voltage value measurement,
wherein, each of the semiconductor devices includes,
a battery cell selection section that selects the battery cells to be subjected to measurement from out of the specific number of the connected battery cells,
a first buffer amplifier, to which is input a voltage of one terminal of the battery cell selected by the battery cell selection section, that is capable of outputting a first voltage according to the voltage of the one terminal of the battery cell, and that is driven by a drive voltage supplied from the battery,
a second buffer amplifier, to which is input a voltage of the other terminal of the battery cell selected by the battery cell selection section, that is capable of outputting a second voltage according to the voltage of the other terminal of the battery cell, and that is driven by a drive voltage supplied from the battery,
a level shifter capable of outputting a difference between the first voltage and the second voltage,
a boost section that boosts the drive voltage supplied from the battery to the first buffer amplifier and the second buffer amplifier,
a battery cell number setting section that is settable with the specific number, and
a control section that is capable of controlling the battery cell selection section and the boost section during performing measurement of voltage values of the battery cells, based on the specific number set in the battery cell number setting section.

2. The battery monitoring system of claim 1, wherein the plurality of semiconductor devices includes the semiconductor devices that have mutually different values for the specific number.

3. The battery monitoring system of claim 1, wherein the control device sets the specific number in the battery cell number setting section for each of the plurality of semiconductor devices.

4. The battery monitoring system of claim 1, wherein each of the plurality of semiconductor devices is equipped with the same number of a plurality of terminals electrically connected to the battery cell selection section, and out of the plurality of terminals, the same electrical potential is applied to any of the terminals not connected to one of the battery cells as is applied to the terminals to which one of the battery cells is connected.

5. The battery monitoring system of claim 1, wherein the boost section is input with the highest voltage of the battery cells of the battery that are connected to the semiconductor device itself, and the highest voltage is boosted.

6. The battery monitoring system of claim 1, wherein, over a period for measuring voltage values of the battery cells subjected to measurement within a predetermined range from the highest voltage side out of the battery cells connected to the semiconductor device itself, the drive voltage is boosted and supplied to the first buffer amplifier and the second buffer amplifier.

7. The battery monitoring system of claim 1, wherein numbers of the first buffer amplifiers and the second buffer amplifiers provided are less than the specific number of the battery cells to be subjected to measurement by the semiconductor device.

8. The battery monitoring system of claim 1, wherein the plurality of semiconductor devices are connected to each other in a daisy chain, and the plurality of semiconductor devices includes a first semiconductor device capable of communicating directly with the control device, and a second semiconductor device capable of communicating with the control device via the first semiconductor device.

9. The battery monitoring system of claim 1, wherein the control section performs setting of the specific number in the battery cell number setting section by:
determining whether or not an output value of the level shifter during measurement of the voltage value of the battery cell is a specific value or greater; and
setting a number of the battery cells for which the output value is the specific value or greater as the specific number in the battery cell number setting section.

10. A semiconductor device that, for a battery configured by connecting a plurality of battery cells together in series, has a specific number of the battery cells out of the plurality of battery cells connected thereto and is capable of measuring respective voltage values of the connected battery cells, wherein the semiconductor device comprises:
a battery cell selection section that selects the battery cells to be subjected to measurement from out of the specific number of the connected battery cells;
a first buffer amplifier, to which is input a voltage of one terminal of the battery cell selected by the battery cell selection section, that is capable of outputting a first voltage according to the voltage of the one terminal of the battery cell, and that is driven by a drive voltage supplied from the battery;
a second buffer amplifier, to which is input a voltage of the other terminal of the battery cell selected by the battery cell selection section, that is capable of outputting a second voltage according to the voltage of the other terminal of the battery cell, and that is driven by a drive voltage supplied from the battery;
a level shifter capable of outputting a difference between the first voltage and the second voltage;
a boost section that boosts the drive voltage supplied from the battery to the first buffer amplifier and the second buffer amplifier;
a battery cell number setting section that is settable with the specific number; and
a control section that is capable of controlling the battery cell selection section and the boost section during performing measurement of voltage values of the battery cells, based on the specific number set in the battery cell number setting section.

11. The semiconductor device of claim 10, wherein, over a period for measuring voltage values of the battery cells subjected to measurement within a predetermined range from the highest voltage side out of the battery cells connected to the semiconductor device itself, the boost section boosts the drive voltage and supplies the boosted drive voltage to the first buffer amplifier and the second buffer amplifier.

12. The semiconductor device of claim 10, wherein numbers of the first buffer amplifiers and the second buffer amplifiers provided are less than the specific number of the battery cells to be subjected to measurement by the semiconductor device itself.

13. The semiconductor device of claim 10, wherein there are a plurality of the semiconductor devices, and each of the plurality of semiconductor devices is equipped with the same number of terminals, and out of the plurality of terminals, the same electrical potential is applied to any of the terminals not connected to one of the battery cells as is applied to the terminals to which one of the battery cells is connected.

14. A battery assembly system comprising:
a battery configured with a plurality of battery cells connected together in series;
a plurality of battery monitoring ICs that detect respective voltages of the battery cells; and
a control IC that is capable of performing instruction to the battery monitoring ICs to detect the respective voltages of each of the battery cells,
wherein each of the battery monitoring ICs includes,
a first buffer amplifier, to which is input a voltage of one terminal of the battery cell subject to voltage detection, that is capable of outputting a first voltage according to the voltage of the one terminal of the battery cell, and that is driven by a drive voltage supplied from the battery,
a second buffer amplifier, to which is input a voltage of the other terminal of the battery cell subject to voltage detection, that is capable of outputting a second voltage according to the voltage of the other terminal of the battery cell, and that is driven by a drive voltage supplied from the battery,
a difference output section that outputs a difference between the first voltage and the second voltage,
a boost section that is capable of boosting drive voltage supplied from the battery to the first buffer amplifier and the second buffer amplifier,
a battery cell number setting section that is settable with a number of the battery cells capable of being detected itself, and
a control section that, according to the detection instruction output from the control IC and the number of the battery cells set by the battery cell number setting section, determines the battery cell to be subjected to voltage detection, and determines whether or not to supply a boosted voltage of the battery to the first buffer amplifier and the second buffer amplifier as the drive voltage.

15. The battery assembly system of claim 14, wherein the battery monitoring ICs further include a battery cell selection section that selects a battery cell to be subjected to detection according to determination of the control section.

16. The battery assembly system of claim 14, wherein:
each of the battery monitoring ICs is connected to a respective specific number of the battery cells out of the battery cells provided to the battery; and
at least two adjacently disposed battery monitoring ICs out of the plurality of battery monitoring ICs have mutually different values for the specific number to be subjected to detection.

17. The battery assembly system of claim 14, wherein the plurality of battery monitoring ICs are connected to each other in a daisy chain, and the plurality of the battery monitoring ICs includes a first battery monitoring IC capable of communicating directly with the control IC, and a second battery monitoring IC capable of communicating with the control IC via the first battery monitoring IC.

18. A battery monitoring IC that, for a battery configured by connecting a plurality of battery cells together in series, detects voltage values of each of the respective battery cells according to an externally input instruction, wherein the battery monitoring IC comprises:
a first buffer amplifier, to which is input a voltage of one terminal of a battery cell subjected to voltage detection, that is capable of outputting a first voltage according to the voltage of the one terminal of the battery cell, and that is driven by a drive voltage supplied from the battery;
a second buffer amplifier, to which is input a voltage of the other terminal of the battery cell subjected to voltage detection, that is capable of outputting a second voltage according to the voltage of the other terminal of the battery cell, and that is driven by a drive voltage supplied from the battery;
a difference output section that outputs a difference between the first voltage and the second voltage;
a boost section that is capable of boosting drive voltage supplied from the battery to the first buffer amplifier and the second buffer amplifier;
a battery cell number setting section that is settable with a number of the battery cells capable of being detected itself; and
a control section that, according to the externally input instruction and the number of the battery cells set in the battery cell number setting section, determines the battery cell to be subjected to voltage detection, and determines whether or not to supply a boosted voltage of the battery to the first buffer amplifier and the second buffer amplifier as the drive voltage.
